(19) United States
(12) Patent Application Publication
(10) Pub. No.: US 2025/0285906 A1
(43) Pub. Date: Sep. 11, 2025

(54) SUBSTRATE PROCESSING METHOD AND SUBSTRATE PROCESSING APPARATUS

(71) Applicant: SCREEN Holdings Co., Ltd., Kyoto (JP)

(72) Inventors: Ryo OKABE, Kyoto (JP); Hiromichi KABA, Kyoto (JP)

(21) Appl. No.: 19/075,385

(22) Filed: Mar. 10, 2025

(30) Foreign Application Priority Data
Mar. 11, 2024 (JP) 2024-037143

(51) Int. Cl. H01L 21/687; B08B 3/04; H01L 21/67; H01L 21/683

(52) U.S. Cl. CPC H01L 21/68728; B08B 3/04; H01L 21/6838; H01L 21/67051; H01L 21/6708

(57) ABSTRACT

A substrate processing method includes a liquid process to supply a processing liquid to a surface of a substrate while holding the substrate in a horizontal state by a center chuck that holds the substrate in a lower surface center portion of the substrate. The method includes a drying process to spin off the liquid on the surface of the substrate by rotating the substrate around a rotation axis along an up/down direction while holding the substrate in a horizontal state by the center chuck and gripping the substrate at an outer circumferential portion of the substrate by an outer circumferential chuck including a plurality of grippers each having a side surface contact portion that comes into contact with an outer circumferential portion side surface of the substrate.

### CROSS REFERENCE TO RELATED APPLICATIONS

This application claims the benefit of priority to Japanese Patent Application No. 2024-037143 filed on Mar. 11, 2024 and the entire contents of this application are hereby incorporated herein by reference.

### BACKGROUND OF THE INVENTION

### 1. Field of the Invention

The present invention relates to a substrate processing method and a substrate processing apparatus for processing substrates. Examples of substrates to be processed include a semiconductor wafer, a substrate for an FPD (flat panel display) such as a liquid crystal display and an organic EL (electroluminescence) display, etc., a substrate for an optical disc, a substrate for a magnetic disc, a substrate for a magneto-optical disc, a substrate for a photomask, a ceramic substrate, a substrate for a solar cell, and the like.

### 2. Description of the Related Art

A single substrate processing type of substrate processing apparatus that supplies a processing liquid to a substrate held in a horizontal state by a spin chuck to perform processing is known. A substrate processing method in such a substrate processing apparatus typically includes a liquid processing step of supplying a processing liquid to a substrate held by a spin chuck, and a drying step of rotating the substrate by rotation of the spin chuck to spin off the liquid.

One type of the spin chuck is one that grips a substrate with a plurality of chuck pins that come into contact with an outer circumferential portion of the substrate, is called a mechanical chuck or the like, and is disclosed in Japanese Patent Application Publication No. 2021-100067, for example. Another type of the spin chuck is one that holds a substrate at a lower surface center portion of the substrate. Spin chucks of this type include a Bernoulli chuck disclosed in Japanese Patent Application Publication No. 2023-45548, and a vacuum chuck that suctions the lower surface center of the substrate.

### SUMMARY OF THE INVENTION

The mechanical chuck holds a substrate by bringing a chuck pin into contact with an outer circumferential portion side surface of the substrate. For this reason, a processing liquid hits the chuck pin and splashes back and the processing liquid is thereby reattached to the surface of the substrate, which causes particles. Also, in the case of processing of removing a film on the surface of the substrate with an etching liquid, there is a possibility that the film remains at a location where the chuck pin is in contact with the substrate, and the film will peel off later and be attached to the substrate surface to become foreign matter. In addition, when the etching liquid is blocked by the chuck pin and flows around to the lower surface of the substrate, the film on the lower surface may peel off, and the film may be attached to the substrate surface and become foreign matter. Further, in a drying step, due to the chuck pin being strongly pressed against the outer circumferential portion side surface in preparation for the high-speed rotation of the substrate, chipping occurs in the substrate or a crack occurs in the film on the outer circumferential portion side surface and a residue is generated, and the residue is attached to the substrate surface and becomes foreign matter, or becomes a contamination source of an apparatus in the next step. As described above, in the mechanical chuck, various phenomena occurring in the outer circumferential portion of the substrate with which the chuck pin is in contact become a problem.

The Bernoulli chuck suctions and holds a substrate by discharging a gas from a fluid head facing the lower surface center portion of the substrate to generate a Bernoulli effect. For this reason, since a member that comes into contact with the outer circumferential portion of the substrate is not required, the above-described problem in the mechanical chuck can be avoided. However, since a substrate holding force obtained by the Bernoulli effect does not reach a substrate holding force obtained by the mechanical chuck, when the substrate is held only by the Bernoulli effect, the upper limit of a substrate rotation speed in the drying step is restricted to, for example, about 1500 rpm. For this reason, since the time required for the drying step is long, the substrate processing time is long, which affects productivity.

Since the vacuum chuck vacuum-suctions the lower surface center portion of the substrate, the vacuum chuck has a substrate holding force larger than that of the Bernoulli chuck. However, when the lower surface center portion of the substrate is strongly suctioned, suction marks remain and the lower surface of the substrate is contaminated, which is a problem. In order to avoid this, it is necessary to reduce a suction force, and it is necessary to accordingly reduce the substrate rotation speed, and the time required for the drying step thereby becomes long.

Therefore, a preferred embodiment of the present invention provides a substrate processing method capable of shortening a drying step while avoiding a problem caused by a member coming into contact with an outer circumferential portion of a substrate during liquid processing, and accordingly contributing to an improvement in productivity. Also, another preferred embodiment of the present invention provides a substrate processing apparatus suitable for carrying out the substrate processing method as described above.

A preferred embodiment of the present invention provides a substrate processing apparatus and a substrate processing method having features which will be exemplified below.
1. A substrate processing method including:
a liquid process to supply a processing liquid to a surface (upper surface or lower surface) of a substrate while holding the substrate in a horizontal state by a center chuck that holds the substrate in a lower surface center portion of the substrate; and
a drying process to spin off the liquid on the surface of the substrate by rotating the substrate around a rotation axis along an up/down direction while holding the substrate in a horizontal state by the center chuck and gripping the substrate at an outer circumferential portion of the substrate by an outer circumferential chuck including a plurality of grippers each having a side surface contact portion that comes into contact with an outer circumferential portion side surface of the substrate.

In this substrate processing method, since the substrate is held by the center chuck in the liquid process, it is not necessary to hold the outer circumferential portion of the substrate. Therefore, it is possible to avoid a problem caused by a member being in contact with the outer circumferential portion of the substrate during the liquid processing. On the other hand, in the drying process, the substrate is held by both the center chuck and the outer circumferential chuck. Therefore, the substrate can be rotated at a higher speed than when the substrate is held only by the center chuck, and the drying processing time can be shortened. Also, since a holding force of the center chuck may be weak, it is, for example, possible to avoid a problem of a suction mark caused by strongly suctioning and holding the center portion of the substrate with a vacuum chuck. Further, since the pressing force of the grippers can be made smaller than when the substrate is held only by the outer circumferential chuck, it is possible to avoid a problem caused by strongly pressing the grippers.
2. The substrate processing method according to item 1, wherein the side surface contact portion of each of the plurality of grippers is retreated from the outer circumferential portion side surface of the substrate in the liquid process, and is brought into contact with the outer circumferential portion side surface of the substrate in the drying process.

According to this method, in the liquid process, since the side surface contact portion of each of the grippers is retreated from the outer circumferential portion side surface of the substrate, the outer circumferential portion side surface of the substrate is in a state of not being in contact with any member over the entire circumference. As a result, it is possible to avoid various problems caused by a member being in contact with the outer circumferential portion of the substrate during the liquid processing.
3. The substrate processing method according to item 1 or 2, further including a centering process to center the substrate by bringing the side surface contact portion of each of the plurality of grippers into contact with the outer circumferential portion side surface of the substrate, wherein
after the centering process, the liquid process is performed by retreating the side surface contact portion of each of the plurality of grippers from the outer circumferential portion of the substrate and bringing the side surface contact portion of each of the plurality of grippers into a non-contact state of not being in contact with the substrate.

By this method, centering, that is, an alignment operation of aligning the substrate center with the rotation axis is performed utilizing the grippers of the outer circumferential chuck, and thereafter, the liquid process can be performed while holding the substrate at the lower surface center portion by the center chuck. Therefore, when the substrate is rotated in the liquid process, the substrate can be stably held by the center chuck.
4. The substrate processing method according to any one of items 1 to 3, wherein, in the drying process, the substrate is rotated around the rotation axis at a predetermined drying rotation speed, and the side surface contact portion of each of the plurality of grippers is pressed against the outer circumferential portion side surface of the substrate with a pressing force smaller than an assumed pressing force required when the substrate is rotated at the drying rotation speed while being held by the outer circumferential chuck without being held by the center chuck.

As described above, in the drying process, since the substrate is held by both the center chuck and the outer circumferential chuck, the pressing force of the grippers against the outer circumferential portion side surface of the substrate may be weak. Therefore, by reducing the pressing force of the grippers, problems such as chipping of the outer circumferential portion of the substrate can be overcome.
5. The substrate processing method according to any one of items 1 to 4, further comprising an elevating/lowering process to move the lower surface supporting portion up and down relative to the center chuck in a state where the substrate is supported from below by the lower surface supporting portion in contact with an outer circumferential portion lower surface of the substrate.

By this method, the substrate can be vertically moved with respect to the center chuck by elevating/lowering the lower surface supporting portion. This facilitates the carry-in and carry-out of the substrate by the substrate transfer robot.
6. The substrate processing method according to item 5, wherein each of the plurality of grippers includes the lower surface supporting portion.

By this method, the substrate can be vertically moved with respect to the center chuck by elevating/lowering the grippers without providing a dedicated lower surface supporting portion. This facilitates the carry-in and carry-out of the substrate by the substrate transfer robot. The substrate may be transferred between the outer circumferential chuck and the center chuck by elevating/lowering the grippers.
7. The substrate processing method according to any one of items 1 to 6, wherein the center chuck includes a Bernoulli chuck.

Although the Bernoulli chuck does not have a large enough substrate holding force to withstand high-speed rotation, there is no problem in holding the substrate during liquid processing that does not require high-speed rotation of the substrate, and there is an advantage that the substrate can be held in a state where the outer circumferential portion side surface of the substrate is released or free of contact by any member. On the other hand, in the drying process, since the substrate is held also by the outer circumferential chuck, it is possible to shorten the drying processing time by rotating the substrate at a high speed. In addition, due to the contribution of the Bernoulli chuck to the holding of the substrate, the pressing force of the grippers of the outer circumferential chuck against the outer circumferential portion side surface of the substrate can be reduced, and it is thereby made possible to prevent a defect or the like in the outer circumferential portion of the substrate.
8. The substrate processing method according to any one of items 1 to 6, wherein the center chuck includes a vacuum chuck.

Since the vacuum chuck can hold the substrate in a state where the outer circumferential portion side surface of the substrate is released, the outer circumferential portion side surface of the substrate can be thoroughly processed in the liquid process. On the other hand, in the drying process, since the substrate is held also by the outer circumferential chuck, it is not necessary to strongly suction the lower surface center portion of the substrate by the vacuum chuck, and thus, it is possible to shorten the drying processing time by rotating the substrate at a high speed while preventing generation of a suction mark. In addition, due to the contribution of the vacuum chuck to the holding of the substrate, the pressing force of the grippers of the outer circumferential chuck against the outer circumferential portion side surface of the substrate can be reduced, and it is thereby made possible to prevent a defect or the like in the outer circumferential portion of the substrate.
9. A substrate processing apparatus including:
a hybrid chuck including a center chuck to hold a substrate at a lower surface center portion of the substrate and an outer circumferential chuck that includes a plurality of grippers that come into contact with an outer circumferential portion side surface of the substrate, the center chuck and the outer circumferential chuck being disposed to share a predetermined rotation axis along a vertical direction;
a lift to move the plurality of grippers up and down relative to the center chuck; and
a gripper actuator to displace the plurality of grippers between a closed state where the plurality of grippers are in contact with the outer circumferential portion side surface of the substrate and an open state where the plurality of grippers are retreated from the outer circumferential portion side surface of the substrate.

With this configuration, a substrate processing apparatus suitable for carrying out the above-described substrate processing method can be provided.
10. The substrate processing apparatus according to item 9, wherein each of the plurality of grippers includes a side surface contact portion that comes into contact with the outer circumferential portion side surface of the substrate and a lower surface supporting portion that comes into contact with an outer circumferential portion lower surface of the substrate.
11. The substrate processing apparatus according to item 10, further including a controller that controls the lift and the gripper actuator, wherein
the controller is configured or programmed to move the plurality of grippers up and down relative to the center chuck in a state where the substrate is supported from below by the lower surface supporting portion.
12. The substrate processing apparatus according to item 11, wherein
the controller configured or programmed to further control the center chuck, and wherein
the controller is configured or programmed to bring the side surface contact portion of each of the plurality of grippers into contact with the outer circumferential portion side surface of the substrate to perform centering of the substrate (alignment of aligning the substrate center with the rotation axis), then retreats the side surface contact portion from the outer circumferential portion side surface of the substrate, and thereafter causes the center chuck to hold the substrate.
13. The substrate processing apparatus according to any one of items 9 to 12, further including:
a processing liquid nozzle to supply a processing liquid to the substrate held by the hybrid chuck; and
a controller configured or programmed to control the center chuck and the outer circumferential chuck, wherein
the controller is configured or programmed
to control the center chuck to be in a holding state in which the center chuck holds the substrate and controls the outer circumferential chuck to be in a non-holding state in which the outer circumferential chuck is not in contact with the substrate in a liquid process in which the processing liquid is supplied from the processing liquid nozzle to the substrate held by the hybrid chuck, and
to controls both the center chuck and the outer circumferential chuck to be in a holding state in which both the center chuck and the outer circumferential chuck hold the substrate in a drying process to stop supplying of the processing liquid from the processing liquid nozzle and to dry the substrate by rotating the substrate at a predetermined drying rotation speed around the rotation axis.
14. The substrate processing apparatus according to item 13, wherein the controller is configured or programmed to rotate the substrate around the rotation axis at the predetermined drying rotation speed, and to control the gripper actuator such that the plurality of grippers are pressed against the outer circumferential portion side surface of the substrate with a pressing force smaller than an assumed pressing force required when the substrate is rotated at the predetermined drying rotation speed while being held by the outer circumferential chuck without being held by the center chuck, in the drying process.
15. The substrate processing apparatus according to item 14, wherein the gripper actuator varies (preferably continuously varies) the pressing force of the plurality of grippers against the outer circumferential portion side surface of the substrate.
16. The substrate processing apparatus according to any one of items 9 to 15, wherein the center chuck includes a Bernoulli chuck.
17. The substrate processing apparatus according to any one of items 9 to 15, wherein the center chuck includes a vacuum chuck.

The above and yet other objects, features, and effects of the present invention will become more apparent from the following description of the preferred embodiments made with reference to the attached drawings.

### BRIEF DESCRIPTION OF THE DRAWINGS

FIG. 1 is a schematic plan view illustrating a layout of a substrate processing system including a substrate processing apparatus according to a preferred embodiment of the present invention.

FIG. 2 is a side view illustrating a configuration example of a processing unit (an example of the substrate processing apparatus) and part of the configuration is illustrated in a vertical cross-sectional view.

FIG. 3 is a block diagram for explaining an electrical configuration of the substrate processing apparatus.

FIG. 4A is a vertical cross-sectional view illustrating a configuration example of a hybrid chuck.

FIG. 4B is a plan view illustrating the configuration example of the hybrid chuck.

FIGS. 5A to 5C are schematic cross-sectional views for explaining a configuration example of an outer circumferential chuck.

FIG. 6 is a flowchart for explaining an example of substrate processing.

FIGS. 7A to 7D are schematic cross-sectional views illustrating states of the hybrid chuck in main steps.

FIGS. 8A to 8D are cross-sectional views for explaining another preferred embodiment of the present invention, and show another configuration example of the hybrid chuck.

FIGS. 9A and 9B are diagrams for explaining still another preferred embodiment of the present invention, and show another configuration example of the outer circumferential chuck.

### DETAILED DESCRIPTION OF THE PREFERRED EMBODIMENTS

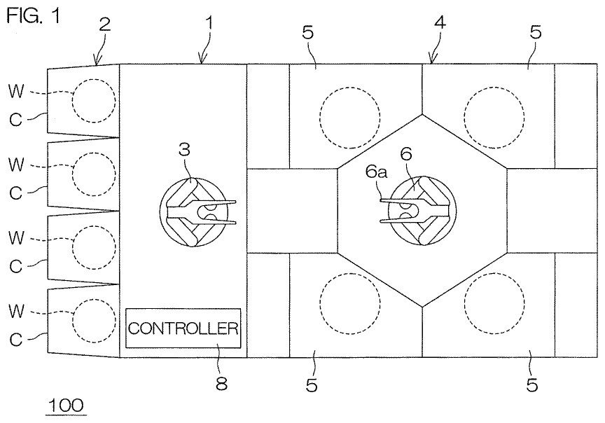

FIG. 1 is a schematic plan view illustrating a layout of a substrate processing system 100 including a substrate processing apparatus according to a preferred embodiment of the present invention. The substrate processing system 100 is a system that processes a substrate W such as a semiconductor substrate. The substrate processing system 100 includes an indexer block 1 and a processing block 4 coupled to the indexer block 1.

The indexer block 1 includes a carrier holding portion 2 and an indexer robot 3. The carrier holding portion 2 is configured to be able to hold a plurality of carriers C each capable of accommodating a plurality of substrates W. The plurality of carriers C (for example, front opening unified pods (FOUPs)) are held in the carrier holding portion 2 in a state of being arranged in a predetermined carrier arrangement direction (an up/down direction in FIG. 1). The indexer robot 3 is movable in the carrier arrangement direction. The indexer robot 3 performs a carry-out operation of carrying each of the substrates W out of the carrier C and a carry-in operation of carrying the substrate W into the carrier C held by the carrier holding portion 2. The substrate W is transferred in a horizontal posture by the indexer robot 3.

The processing block 4 includes a plurality of processing units 5 to process the substrates W and a center robot 6 (a substrate transfer robot). The plurality of processing units 5 is disposed such as to surround the center robot 6 in a plan view, and further, may be stacked in a plurality of layers in an up/down direction. In the plurality of processing units 5, various types of processing are performed on the substrate W. Each of the processing units 5 is an example of a substrate processing apparatus. The center robot 6 performs a carry-in operation of carrying the substrate W into the processing unit 5 and a carry-out operation of carrying the substrate W out of the processing unit 5. Further, the center robot 6 can also transfer the substrate W between the plurality of processing units 5. The substrate W is horizontally held by a hand 6a of the center robot 6 and transferred in a horizontal posture. The center robot 6 receives an untreated substrate W from the indexer robot 3, and delivers the processed substrate W to the indexer robot 3.

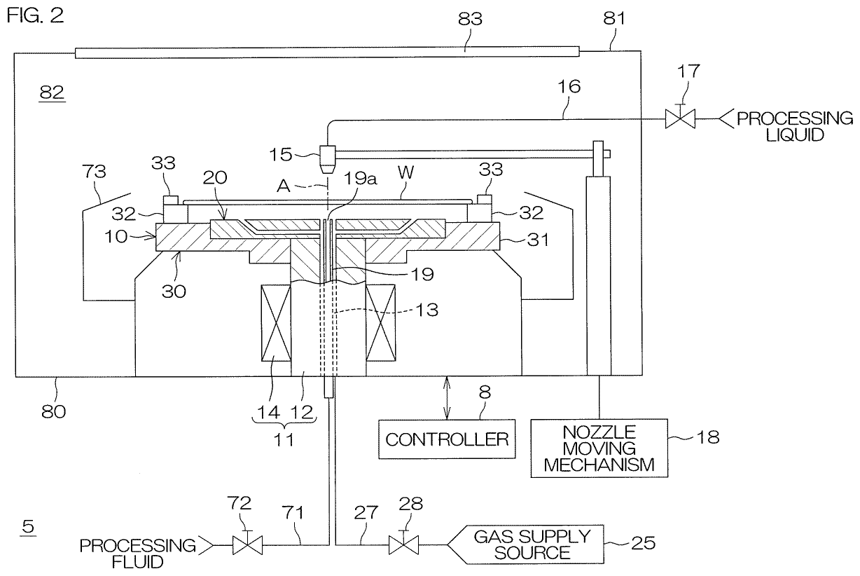

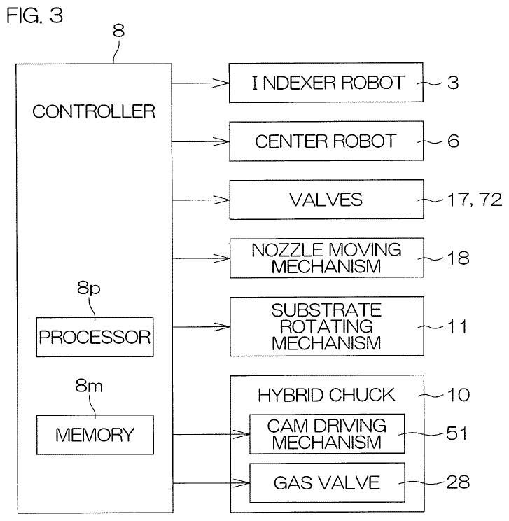

FIG. 2 is a side view illustrating a configuration example of the processing unit 5 (an example of the substrate processing apparatus) and part of the configuration is illustrated in a vertical cross-sectional view. The processing unit 5 is a single substrate processing type of substrate processing apparatus that processes the substrates W one by one. The processing unit 5 performs liquid process to supply the processing liquid to the substrate W and drying process to spin off the liquid on the substrate W after the liquid process. The processing liquid may be a chemical liquid or a rinse liquid. The chemical liquid may be a cleaning liquid for cleaning the surface of the substrate W or an etching liquid for etching process. Although the rinse liquid is typically deionized water (DIW), other types of liquids such as carbonated water and isopropyl alcohol (IPA) may also be used as the rinse liquid.

The processing unit 5 includes a hybrid chuck 10, a substrate rotating mechanism 11, a processing liquid nozzle 15, a nozzle moving mechanism 18, a lower surface nozzle 19, a processing cup 73, a controller 8, and a chamber 80.

The hybrid chuck 10 is a substrate holding portion or a substrate holder to hold one substrate W in a horizontal posture. The substrate rotating mechanism 11 is a rotation actuator to rotate the substrate W around a vertical rotation axis A passing through the center of the substrate W. More specifically, the substrate rotating mechanism 11 rotates the hybrid chuck 10 around the rotation axis A.

The processing liquid nozzle 15 supplies the processing liquid to the surface (the upper surface) of the substrate W held and rotated by the hybrid chuck 10. The processing liquid is supplied to the processing liquid nozzle 15 through a processing liquid piping 16. A processing liquid valve 17 is interposed in the middle of the processing liquid piping 16. In this preferred embodiment, the processing liquid nozzle 15 is a moving nozzle movable by the nozzle moving mechanism 18. The nozzle moving mechanism 18 is a nozzle actuator to move the processing liquid nozzle 15 between a processing position above the substrate W held by the hybrid chuck 10 and a retreat position retreated laterally from above the substrate W.

The lower surface nozzle 19 has a discharge port 19a facing the lower surface center of the substrate W held by the hybrid chuck 10, and supplies a processing fluid (a liquid or a gas; for example, an inert gas such as nitrogen gas or dry air) toward the lower surface center of the substrate W. The lower surface nozzle 19 is disposed inside a shaft 12 of the substrate rotating mechanism 11. The processing fluid is supplied to the lower surface nozzle 19 through a processing fluid piping 71. A processing fluid valve 72 is interposed in the processing fluid piping 71.

The processing cup 73 is disposed such as to surround the hybrid chuck 10, and captures a liquid discharged outward from the substrate W by a centrifugal force. A bottom portion of the processing cup 73 is provided with a liquid discharge port (not illustrated) for discharging the captured liquid to the outside of the chamber 80.

The hybrid chuck 10, the substrate rotating mechanism 11, the processing cup 73, the processing liquid nozzle 15, and the like are accommodated in an internal space 82 of the chamber 80. A canopy portion 81 of the chamber 80 is provided with an airflow forming portion 83 that supplies a gas to the internal space 82 of the chamber 80 to form a downward flowing airflow (so-called downflow). As the airflow forming portion 83, for example, a fan filter unit (FFU) is utilized.

The hybrid chuck 10 and the substrate rotating mechanism 11 compose a spin chuck to hold a substantially disk-shaped substrate W in a horizontal posture and to rotate the substrate W around the rotation axis A along a vertical direction. The substrate rotating mechanism 11 is disposed below the hybrid chuck 10. The substrate rotating mechanism 11 rotates the substrate W together with the hybrid chuck 10 about the rotation axis A. The substrate rotating mechanism 11 includes the shaft 12 and an electric motor 14. The shaft 12 is a substantially cylindrical member centered on the rotation axis A. The shaft 12 extends in the up/down direction and is connected to the hybrid chuck 10. The electric motor 14 rotates the shaft 12. The electric motor 14 may be a hollow motor.

The controller 8 is disposed outside the chamber 80. The controller 8 is, for example, a computer system including a processor 8p and a memory 8m. The processor 8p executes various types of processing according to a program or the like stored in the memory 8m. Accordingly, the controller 8 is configured or programmed to control the operation of a control target such as the indexer robot 3, the center robot 6, the hybrid chuck 10, the substrate rotating mechanism 11, the nozzle moving mechanism 18, and the valves 17 and 72.

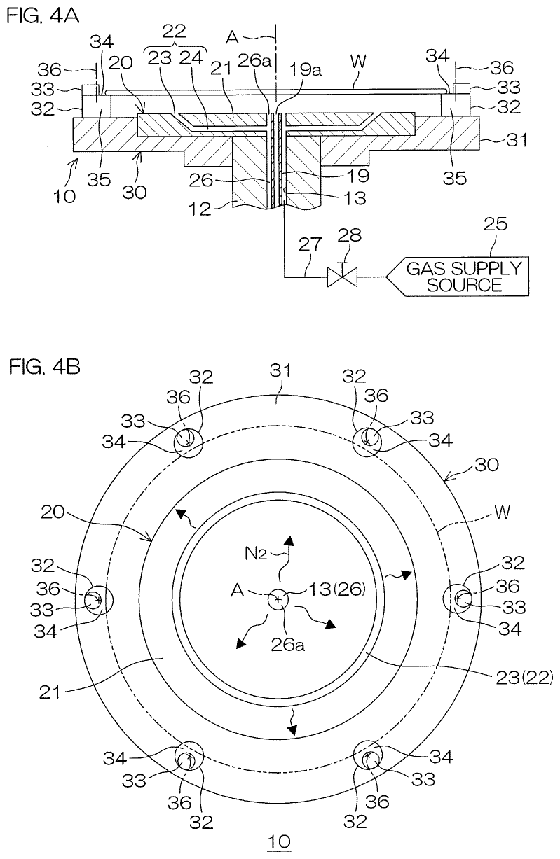

FIG. 4A is a vertical cross-sectional view illustrating a configuration example of the hybrid chuck 10, and FIG. 4B is a plan view of the hybrid chuck 10. In FIG. 4B, the substrate W held by the hybrid chuck 10 is indicated by an alternate long and two short dashed line.

The hybrid chuck 10 is configured by combining and integrating center chuck 20 and an outer circumferential chuck 30 such as to share the rotation axis A. The center chuck 20 is configured to hold the substrate W in a horizontal state at the lower surface center portion of the substrate W. The outer circumferential chuck 30 includes a plurality of gripping members or grippers 32 that are configured to come into contact with the outer circumferential portion side surface of the substrate W. The center chuck 20 and the outer circumferential chuck 30 can hold the substrate W in a horizontal state by only one of them, and can hold the substrate W in a horizontal state by both of them.

The outer circumferential chuck 30 includes a disk-shaped base 31 (hereinafter referred to as “outer circumferential base 31”) and the plurality of grippers 32 protruding upward from a circumferential edge portion of the outer circumferential base 31. In this example, six grippers 32 are disposed at equal intervals on a circumference about the rotation axis A. The outer edge of the outer circumferential base 31 is located radially (in a radial direction centered on the rotation axis A) more outward than the outer circumferential edge of the substrate W, and the grippers 32 are disposed radially more outward than the outer circumferential edge of the substrate W.

Each of the grippers 32 is composed of a gripping pin extending along the vertical direction, and the upper end portion thereof is provided with a side surface contact portion 33 that is to come into contact with the outer circumferential portion side surface of the substrate W and a lower surface supporting portion 34 that is to come into contact with the outer circumferential portion lower surface of the substrate W. The side surface contact portion 33 faces the outer circumferential portion side surface of the substrate W, and the lower surface supporting portion 34 faces the outer circumferential portion lower surface of the substrate W. Each of the grippers 32 is configured to be displaceable between a closed state in which the side surface contact portion 33 is in contact with the outer circumferential portion side surface of the substrate W and an open state in which the side surface contact portion 33 is retreated from the outer circumferential portion side surface of the substrate W. More specifically, when the gripper 32 turns around a circumrotation axis 36 along the vertical direction, a distance between the side surface contact portion 33 and the rotation axis A varies, and accordingly, a distance between the side surface contact portion 33 and the outer circumferential portion side surface of the substrate W varies.

Further, in this example, the grippers 32 are configured to be vertically movable up and down with respect to the outer circumferential base 31, thereby to mediate the transfer of the substrate W between the center robot 6 and the hybrid chuck 10, and are configured to be able to transfer the substrate W between the outer circumferential chuck 30 (more specifically, the lower surface supporting portions 34 of the grippers 32) and the center chuck 20.

The center chuck 20 is incorporated in the center portion of the outer circumferential base 31. In this example, the center chuck 20 is a Bernoulli chuck to suction and hold the substrate W by a Bernoulli effect. The center chuck 20 includes a base 21 (hereinafter referred to as “center base 21”) and a gas supplying portion 22 which are incorporated in the center portion of the outer circumferential base 31. The center base 21 is a substantially disk-shaped member centered on the rotation axis A. The center base 21 has an upper surface (a suction surface) facing the lower surface of the substrate W. The upper surface of the center base 21 is a substantially horizontal plane. The diameter of the center base 21 is smaller than the diameter of the substrate W, and the outer edge of the upper surface of the center base 21 is located radially more inward than the outer circumferential edge of the substrate W.

The gas supplying portion 22 includes a gas discharge port 23 opened on the upper surface of the center base 21 and a gas flow path 24 for supplying a gas to the gas discharge port 23. In this preferred embodiment, the gas discharge port 23 is an annular slit opening centered on the rotation axis A. Instead of such one annular slit opening, a plurality of discrete openings arranged in an annular shape may be used as the gas discharge port 23. The gas discharge port 23 is connected to a gas supply source 25 via the gas flow path 24 provided inside the center base 21.

The outer circumferential base 31 and the center base 21 are coupled to the shaft 12 of the substrate rotating mechanism 11. The shaft 12 is a hollow shaft having a through hole 13 passing through thereof in the axial direction. The lower surface nozzle 19 passes through the through hole 13. A gas supply passage 26 is formed between the lower surface nozzle 19 and the inner circumferential surface of the through hole 13, and the gas supply passage 26 communicates with the gas flow path 24. The gas supply passage 26 has a gas discharge port 26a opened at an upper surface center of the center base 21, and can discharge a gas from the gas discharge port 26a toward the lower surface center of the substrate W. A gas can be supplied from the gas supply source 25 to the gas supply passage 26 via a gas piping 27. The gas may be, for example, an inert gas such as nitrogen gas, or air, etc. This gas is, for example, a high-pressure gas or a compressed gas. When a gas valve 28 provided in the gas piping 27 is opened, the gas supplied from the gas supply source 25 passes through the gas supply passage 26 and the gas flow path 24, is discharged from the gas discharge port 23, and is discharged from the gas discharge port 26a at the center of the center base 21.

The gas flow path 24 obliquely extends radially outward and upward in the vicinity of the gas discharge port 23. The gas discharge port 23 is disposed such as to open below the substrate W at a position more inward than the outer circumference of the substrate W. Therefore, the gas is discharged radially outward and upward from the gas discharge port 23 toward the lower surface of the substrate W. This gas flows substantially horizontally, radially outward along the lower surface of the substrate W. Also, the gas discharged from the gas discharge port 26a at the center of the center base 21 also flows radially outward along the lower surface of the substrate W. As a result, an air flow directed radially outward from a radial center portion is formed in a space below the substrate W, and a pressure drop in the space below the substrate W occurs due to a Bernoulli effect by the air flow. As a result, the center portion of the substrate W is suctioned to the center chuck 20.

When the flow rate of the gas discharged from the gas discharge ports 23 and 26a increases, the downward suction force acting on the substrate W increases accordingly. When the discharge of the gas is stopped, the suction force is lost.

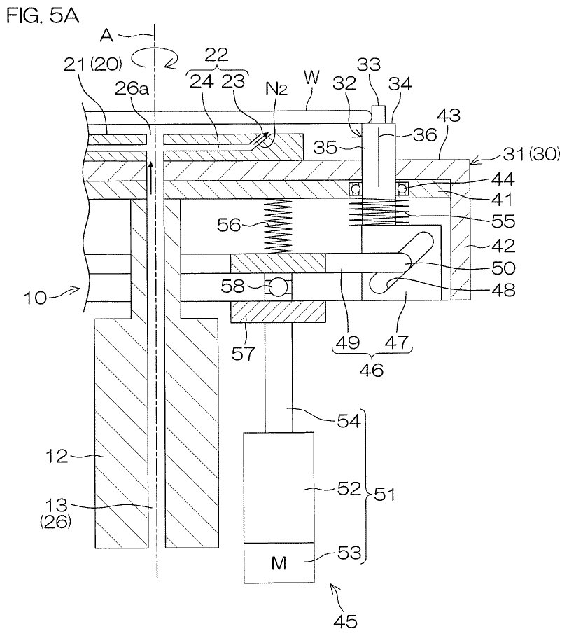

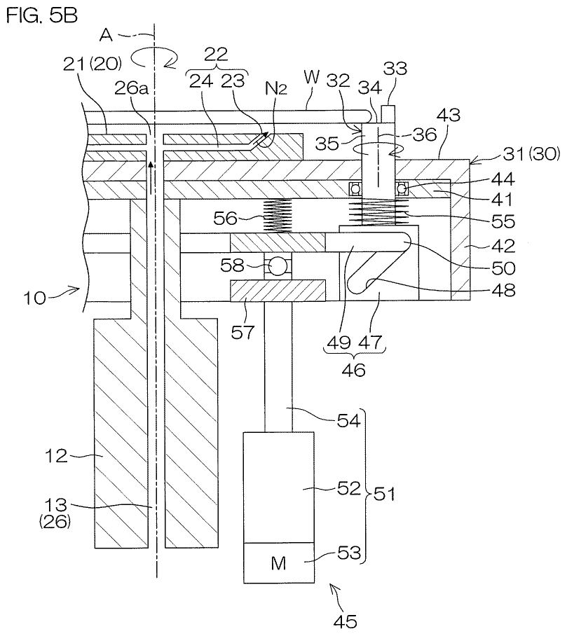

FIGS. 5A, 5B, and 5C are schematic cross-sectional views for explaining a configuration example of the outer circumferential chuck 30. The outer circumferential base 31 includes a base plate 41 fixed to the shaft 12 and a base cover 42 coupled to the base plate 41. The base plate 41 is accommodated in the base cover 42. Each of the grippers 32 is coupled to the base plate 41 via a bearing 44. Each of the grippers 32 includes a shaft portion 35 that passes through the base plate 41 in the up/down direction, further passes through a top surface portion 43 of the base cover 42 and protrudes upward, and the lower surface supporting portion 34 and the side surface contact portion 33 are provided at an upper end portion of the shaft portion 35. The bearing 44 couples the shaft portion 35 of the gripper 32 to the base plate 41 such as to be circumrotatable about the circumrotation axis 36 and guide up/down movement with respect to the base plate 41. The side surface contact portion 33 is erected at a position eccentric from the circumrotation axis 36. Therefore, the distance between the side surface contact portion 33 and the outer circumferential portion side surface of the substrate W changes by the circumrotation of the gripper 32 about the circumrotation axis 36.

A gripper driving mechanism 45 is provided, and is configured to turn each of the grippers 32 around the circumrotation axis 36 and to move each of the grippers 32 up and down. The gripper driving mechanism 45 includes a cam mechanism 46 and a cam driving mechanism 51 that applies a driving force to the cam mechanism 46.

The cam mechanism 46 includes a cam follower 47 fixed to a lower end of the shaft portion 35 of the gripper 32 and a cam lever 49 coupled to the cam follower 47. A compression coil spring 55 is wound around the shaft portion 35 of the gripper 32 between the cam follower 47 and the base plate 41 to bias the cam follower 47 and the gripper 32 downward. The cam lever 49 is accommodated in the base cover 42 and is movable up and down below the base plate 41. The cam follower 47 has a cam groove 48 inclined with respect to the up/down direction, and a drive end 50 of the cam lever 49 is coupled to the cam groove 48. A compression coil spring 56 that pushes down the cam lever 49 is disposed between the cam lever 49 and the lower surface of the base plate 41.

The cam driving mechanism 51 is disposed in a non-rotating system outside the base cover 42. The cam driving mechanism 51 includes a ball-screw mechanism 52, an electric motor 53 that applies a driving force to the ball-screw mechanism 52, and a driving rod 54 that is moved up and down by the ball-screw mechanism 52. A ring-shaped elevating/lowering plate 57 surrounding the rotation axis A is coupled to an upper end of the driving rod 54. A ring-shaped ball bearing 58 surrounding the rotation axis A is disposed between the elevating/lowering plate 57 and the cam lever 49. One bearing ring of the ball bearing 58 is coupled to the elevating/lowering plate 57, and the other bearing ring of the ball bearing 58 is coupled to the cam lever 49.

When the cam driving mechanism 51 is driven, the elevating/lowering plate 57 moves up and down, and this up/down movement is transmitted to the cam lever 49 via the ball bearing 58, and the cam lever 49 also moves up and down. Then, the drive end 50 of the cam lever 49 moves in the cam groove 48 of the cam follower 47 to radially displace the cam follower 47. As a result, the gripper 32 circumrotates around the circumrotation axis 36. As a result, the distance between the side surface contact portion 33 and the rotation axis A, that is, the distance between the side surface contact portion 33 and the outer circumferential portion side surface of the substrate W varies.

In this preferred embodiment, it is configured such that, when the cam lever 49 is lowered and the cam follower 47 is displaced radially outward, the side surface contact portion 33 is displaced in a direction approaching the rotation axis A and approaches the outer circumferential portion side surface of the substrate W. Therefore, as illustrated in FIG. 5A, by lowering the cam lever 49, the side surface contact portion 33 can be brought into contact with the outer circumferential portion side surface of the substrate W, and the side surface contact portion 33 can be pressed against the outer circumferential portion side surface of the substrate W. That is, the gripper 32 can be brought into a closed state. The pressing force of the side surface contact portion 33 against the outer circumferential portion side surface of the substrate W is continuously variable by changing the driving force applied from the cam driving mechanism 51 including the ball-screw mechanism 52, that is, a torque generated by the electric motor 53.

When the cam driving mechanism 51 elevates the elevating/lowering plate 57 to elevate the cam lever 49, the cam follower 47 is displaced radially inward as illustrated in FIG. 5B. Then, the side surface contact portion 33 is displaced in a direction away from the rotation axis A, and is separated from the outer circumferential portion side surface of the substrate W. As a result, the gripper 32 can be brought into an open state.

When the cam lever 49 is further elevated by the cam driving mechanism 51 from the state in which the drive end 50 of the cam lever 49 reaches the upper end of the cam groove 48, the cam follower 47 can be elevated as illustrated in FIG. 5C, and the gripper 32 can thereby be elevated to the upper position. As a result, the outer circumferential portion lower surface of the substrate W can be supported by the lower surface supporting portion 34 of the gripper 32 to lift the substrate W. When the cam lever 49 is lowered by the cam driving mechanism 51 from this state, the cam follower 47 is pushed down by the compression coil spring 55, and accordingly, the gripper 32 can be lowered to the lower position illustrated in FIG. 5B. In this way, the gripper 32 moves up and down between the upper position (see FIG. 5C) and the lower position (see FIGS. 5A and 5B), thereby having a function as a lift pin that moves the substrate W in the up/down direction. The gripper driving mechanism 45 is an elevating/lowering mechanism or a lift to move the gripper 32 up and down relative to the center chuck 20, and is also an opening/closing mechanism or a gripper actuator to displace the gripper 32 between the closed state and the open state. As a matter of course, it may be configured such that the elevating/lowering mechanism and the opening/closing mechanism are separately provided.

The upper position of the gripper 32 is a transfer position at which the substrate W is transferred between the hand 6a (see FIG. 1) of the center robot 6 (the substrate transfer robot) and the hybrid chuck 10. The lower position of the gripper 32 is a position where the substrate W can be held by the center chuck 20. Therefore, the lower position is a position where both the outer circumferential chuck 30 and the center chuck 20 can hold the substrate W, and is thus a position where the substrate W can be transferred between the outer circumferential chuck 30 and the center chuck 20. When the gripper 32 is at the lower position, the substrate W can be held only by the center chuck 20 with the gripper 32 in the open state (see FIG. 5B). Also, when the gripper 32 is at the lower position, the substrate W can be held (gripped) by the outer circumferential chuck 30 with the gripper 32 in the closed state. Therefore, as illustrated in FIG. 5A, the substrate W can be held by the lower surface center portion of the substrate W by the center chuck 20, and the substrate W can be held at the outer circumferential portion of the substrate W by the outer circumferential chuck 30.

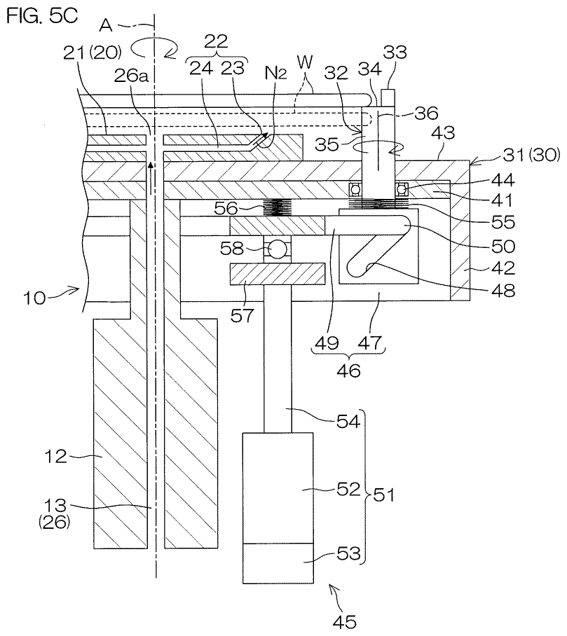

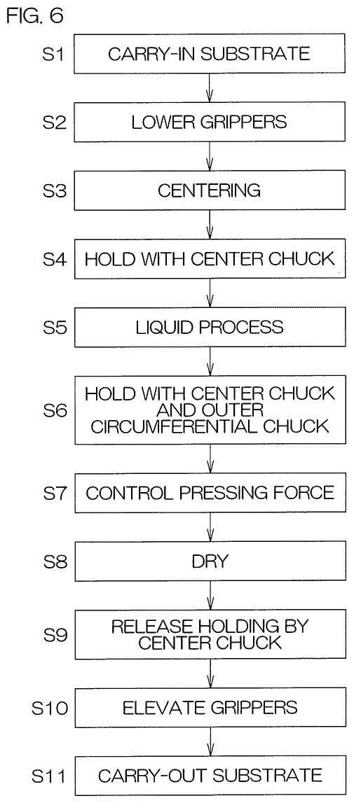

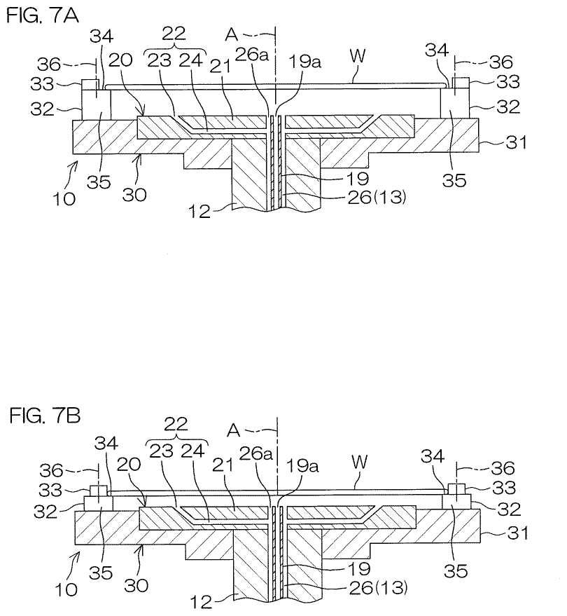

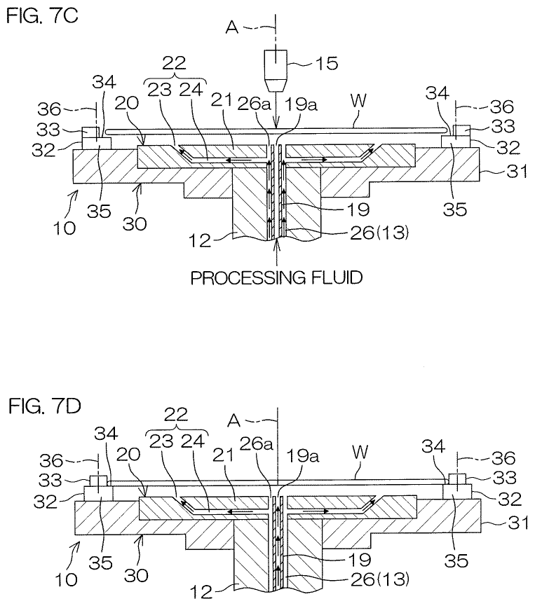

FIG. 6 is a flowchart for explaining an example of substrate processing. Also, FIGS. 7A to 7D are schematic cross-sectional views illustrating states of the hybrid chuck 10 in main steps. An operation of each step which will be described below is achieved by the controller 8 controlling each portion according to a predetermined program and a substrate processing recipe.

The substrate W to be processed is carried into the processing unit 5 by the center robot 6 and delivered to the outer circumferential chuck 30 (step S1). The substrate W delivered to the grippers 32 is supported in a horizontal posture by the lower surface supporting portions 34 of the grippers 32 coming into contact with the outer circumferential portion lower surface of the substrate W. At this time, as illustrated in FIG. 7A, the grippers 32 are disposed at the upper position in the open state under the control of the cam driving mechanism 51 by the controller 8. Also, the discharge of the gas from the gas discharge ports 23 and 26a has been stopped, and thus the center chuck 20 (the Bernoulli chuck) is in an inactive state (a non-suctioning state, a non-holding state).

Next, the controller 8 controls the cam driving mechanism 51 so that the grippers 32 are lowered to the lower position in a state where the substrate W is supported by the lower surface supporting portions 34 (step S2). Further, under the control of the cam driving mechanism 51, the grippers 32 are brought into a closed state, and the side surface contact portions 33 of the grippers 32 come into contact with the outer circumferential portion side surface of the substrate W. Thereby, alignment, that is, centering is performed to align the center of the substrate W with the rotation axis A (step S3; see FIG. 7B).

Next, the controller 8 opens the gas valve 28 to start gas discharge from the gas discharge port 23, thereby the center chuck 20 (the Bernoulli chuck) is brought into an operating state (a suctioning state, a holding state) (step S4; see FIG. 7C). Then, under the control of the cam driving mechanism 51, the grippers 32 are brought into the open state (the non-holding state), and the holding by the outer circumferential chuck 30 is released. As a result, the substrate W is delivered from the outer circumferential chuck 30 to the center chuck 20, and the substrate W is held only by the center chuck 20. At this time, the grippers 32 are not in contact with either the side surface or the lower surface of an outer circumferential portion (a bevel) of the substrate W, and the substrate W is held by the center chuck 20 in a bevel-free state. Since the Bernoulli chuck suctions the substrate W by generating an airflow on the lower surface of the substrate W, the substrate W is held by the center chuck 20 in a state where the substrate W is floating upward from the lower surface supporting portions 34 of the grippers 32. As necessary, the grippers 32 may be slightly lowered in order to secure an interval between the outer circumferential portion lower surface of the substrate W and the lower surface supporting portions 34.

In this manner, the liquid process to supply the processing liquid to the surface of the substrate W is performed while rotating the substrate W in a state where the substrate W is held only by the center chuck 20 (step S5; a liquid process; see FIG. 7C). That is, the controller 8 controls the substrate rotating mechanism 11 to cause the hybrid chuck 10 to rotate around the rotation axis A, and the substrate W is thereby rotated around the rotation axis A at a predetermined liquid processing rotation speed (for example, 800 rpm). The liquid processing rotation speed is set to an appropriate value equal to or less than an upper limit rotation speed (for example, 1500 rpm) at which holding and rotating only by the center chuck 20 (the Bernoulli chuck) is possible. Also, when the processing liquid valve 17 is opened by the control of the controller 8, the processing liquid is discharged from the processing liquid nozzle 15 toward the surface (here, the upper surface) of the substrate W. As shown in FIG. 7C, the processing fluid (the processing liquid or a processing gas) may be discharged from the lower surface nozzle 19 as necessary. After the liquid processing is performed for a predetermined liquid processing time, the discharge of the processing liquid from the processing liquid nozzle 15 is stopped.

Next, at the start of a drying process of rotating the substrate W around the rotation axis A at a predetermined drying rotation speed (for example, 2500 rpm) to spin off the liquid, the controller 8 controls the cam driving mechanism 51 to control the grippers 32 to the closed state (holding state). That is, the side surface contact portions 33 of the grippers 32 come into contact with the outer circumferential portion side surface of the substrate W, and holding of the substrate by the outer circumferential chuck 30 is started. That is, the substrate W is held at the lower surface center portion by the center chuck 20 and is held at the outer circumferential portion by the outer circumferential chuck 30 (step S6; see FIG. 7D).

The controller 8 executes pressing force control to adjust the pressing force under the control of the cam driving mechanism 51 (step S7). More specifically, the controller 8 controls the pressing force by controlling the torque generated by the electric motor 53. The pressing force is controlled to a value smaller than an assumed pressing force required when the substrate W is not held by the center chuck 20 but the substrate W is held only by the outer circumferential chuck 30, and the substrate W is rotated at the drying rotation speed. That is, the torque generated by the electric motor 53 is controlled such that such a pressing force is achieved.

The drying process is performed while performing such pressing force control (step S8). That is, the controller 8 accelerates the rotation speed of the substrate W to the drying rotation speed by controlling the substrate rotating mechanism 11, and maintains the drying rotation speed over a predetermined drying time. Thereafter, the rotation of the substrate is stopped, and the drying process is terminated. In the drying process, an inert gas may be discharged from the lower surface nozzle 19 to promote drying.

Next, the controller 8 releases the suctioning and holding by the center chuck 20 (Bernoulli chuck) by closing the gas valve 28 and stopping the discharge of the gas from the gas discharge port 23 (step S9). As a result, the substrate W is brought into a state where being held only by the outer circumferential chuck 30, and the substrate W is transferred from the center chuck 20 to the outer circumferential chuck 30.

Thereafter, the controller 8 controls the cam driving mechanism 51 to bring the grippers 32 into the open state to separate the side surface contact portions 33 thereof from the outer circumferential portion side surface of the substrate W, and further, elevates the gripper 32 to the elevated position in a state where the lower surface supporting portion 34 supports the outer circumferential portion lower surface of the substrate W (step S10; see FIG. 7A). Thereafter, the center robot 6 picks up the processed substrate W from the grippers 32 in the open state and carries out the substrate W (step S11). In this way, the processing on one substrate W is ended.

As described above, in this preferred embodiment, since the substrate W is held by the center chuck 20 in the liquid process, it is not necessary to hold the outer circumferential portion of the substrate W. Therefore, it is possible to avoid a problem caused by a member being in contact with the outer circumferential portion of the substrate W during the liquid process. On the other hand, in the drying process, the substrate W is held by both the center chuck 20 and the outer circumferential chuck 30. Therefore, the substrate W can be rotated at a higher speed than when the substrate W is held only by the center chuck 20, and the drying process time can be shortened. Also, since the pressing force of the grippers 32 can be made smaller than when the substrate W is held only by the outer circumferential chuck 30, it is possible to avoid a problem caused by strongly pressing the grippers 32.

In this preferred embodiment, the side surface contact portion 33 of each of the grippers 32 is retreated from the outer circumferential portion side surface of the substrate W in the liquid process, and is brought into contact with the outer circumferential portion side surface of the substrate in the drying process. Therefore, in the liquid process, the outer circumferential portion side surface of the substrate W is in a state of not being in contact with any member over the entire circumference. As a result, it is possible to avoid various problems caused by a member being in contact with the outer circumferential portion of the substrate W during the liquid processing.

Also, in this preferred embodiment, a centering process to center the substrate W (align the center of the substrate W) by bringing the side surface contact portions 33 of the grippers 32 into contact with the outer circumferential portion side surface of the substrate W performed. Then, after the centering process, the liquid process is executed in such a manner that the side surface contact portions 33 of the grippers 32 are retreated from the outer circumferential portion of the substrate W and the side surface contact portions 33 are brought into a non-contact state of not being in contact with the substrate W. That is, centering, that is, an alignment operation of aligning the substrate center with the rotation axis A is performed utilizing the grippers 32 of the outer circumferential chuck 30, and thereafter, the liquid process can be performed while holding the substrate W at the lower surface center portion by the center chuck 20. Therefore, when the substrate W is rotated in the liquid process, the substrate W can be stably held by the center chuck 20.

Also, in this preferred embodiment, when the substrate W is rotated around the rotation axis A at a predetermined drying rotation speed in the drying process, the side surface contact portions 33 of the grippers 32 are pressed against the outer circumferential portion side surface of the substrate W with a pressing force smaller than an assumed pressing force required when the substrate W is rotated at the drying rotation speed while being held by the outer circumferential chuck 30 without being held by the center chuck 20. In the drying process, since the substrate W is held by both the center chuck 20 and the outer circumferential chuck 30, the pressing force of the grippers 32 against the outer circumferential portion side surface of the substrate W may be weak. Therefore, by reducing the pressing force of the grippers, problems such as chipping of the outer circumferential portion of the substrate W can be overcome.

Also, in this preferred embodiment, the lower surface supporting portion 34 is moved up and down relative to the center chuck 20 in a state where the substrate W is supported from below by the lower surface supporting portion 34 in contact with the outer circumferential portion lower surface of the substrate W (an elevating/lowering process). This facilitates the carry-in and carry-out of the substrate W by the center robot 6 (the substrate transfer robot).

Also, in this preferred embodiment, each of the grippers 32 includes the lower surface supporting portion 34. Therefore, the substrate W can be moved up and down with respect to the center chuck 20 by elevating/lowering the grippers 32 without providing a dedicated lower surface supporting portion.

Also, in this preferred embodiment, the center chuck 20 is a Bernoulli chuck. Although the Bernoulli chuck does not have a large enough substrate holding force to withstand high-speed rotation, there is no problem in holding the substrate W during liquid process that does not require high-speed rotation of the substrate W, and there is an advantage that the substrate W can be held in a state where the outer circumferential portion side surface of the substrate W is released or free of contact by any member. On the other hand, in the drying process, since the substrate W is held also by the outer circumferential chuck 30, it is possible to shorten the drying processing time by rotating the substrate W at a high speed. In addition, due to the contribution of the Bernoulli chuck to the holding of the substrate W, the pressing force of the grippers 32 of the outer circumferential chuck 30 against the outer circumferential portion side surface of the substrate can be reduced, and it is thereby made possible to prevent a defect or the like in the outer circumferential portion of the substrate W.

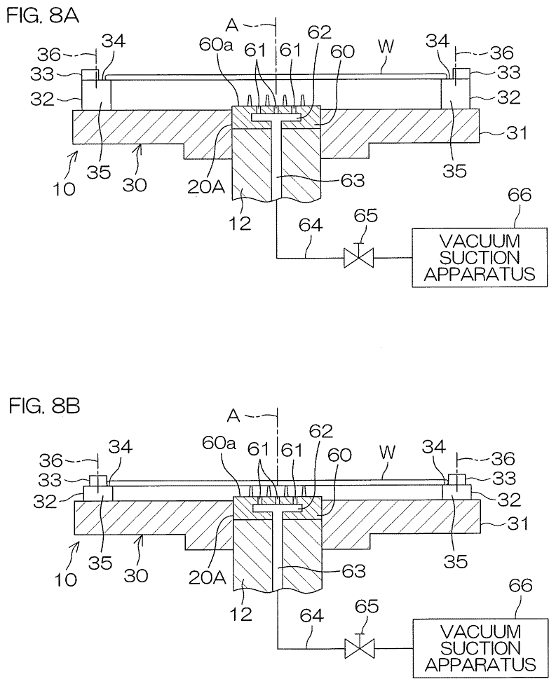

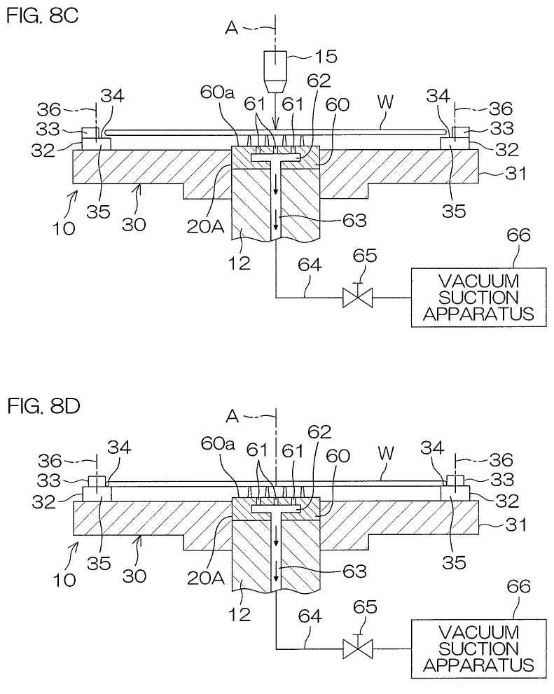

FIGS. 8A to 8D are cross-sectional views for explaining another preferred embodiment of the present invention, and show another configuration example of the hybrid chuck 10. In this preferred embodiment, the hybrid chuck 10 includes the outer circumferential chuck 30 having the same configuration as that of the above-described preferred embodiment, and a center chuck 20A composed of a vacuum chuck. The center chuck 20A composed of the vacuum chuck is configured to hold the substrate W in a horizontal state at the lower surface center portion of the substrate W, and is combined and integrated such as to share the rotation axis A with the outer circumferential chuck 30 to compose the hybrid chuck 10. The center chuck 20A and the outer circumferential chuck 30 can hold the substrate W in a horizontal state by only one of them, and can hold the substrate W in a horizontal state by both of them.

The center chuck 20A composed of a vacuum chuck is incorporated in the center portion of the outer circumferential base 31. The center chuck 20A includes a suction head 60 incorporated in the center portion of the outer circumferential base 31. The suction head 60 includes a plurality of suction holes 61 opened in a suction surface 60a facing the lower surface center of the substrate W, and a suction flow path 62 communicating with the suction holes 61. The suction flow path 62 is connected to a vacuum suction apparatus 66 via a suction path 63 formed in a hollow shaft 12 and a suction piping 64 connected thereto. A suction valve 65 is interposed in the middle of the suction piping 64, and the suction valve 65 is controlled to be opened and closed by the controller 8.

An example of the substrate processing is substantially similar to the case of the above-described preferred embodiment. In the following, FIG. 6 shall be referenced together.

The substrate W to be processed is carried into the processing unit 5 by the center robot 6 (step S1) and delivered to the outer circumferential chuck 30. The substrate W delivered to the grippers 32 is supported in a horizontal posture by the lower surface supporting portions 34 of the grippers 32 coming into contact with the outer circumferential portion lower surface of the substrate W. At this time, as illustrated in FIG. 8A, the grippers 32 are disposed at the upper position in the open state. Also, the suction by the suction head 60 has been stopped, and thus the center chuck 20A (the Bernoulli chuck) is in an inactive state (a non-suctioning state, a non-holding state).

Next, by the control of the cam driving mechanism 51, the grippers 32 are lowered to the lower position in a state where the substrate W is supported by the lower surface supporting portions 34 (step S2). Further, under the control of the cam driving mechanism 51, the grippers 32 are brought into a closed state, and the side surface contact portions 33 of the grippers 32 comes into contact with the outer circumferential portion side surface of the substrate W. Thereby, alignment, that is, centering is performed to align the center of the substrate W with the rotation axis A (step S3; see FIG. 8B).

Next, the controller 8 opens the suction valve 65 to start suction by the suction head 60, thereby the center chuck 20A (vacuum chuck) is brought into an operating state (a suctioning state, a holding state) (step S4; see FIG. 8C). Then, by the control of the cam driving mechanism 51 by the controller 8, the grippers 32 are brought into the open state (the non-holding state), and the holding by the outer circumferential chuck 30 is released. As a result, the substrate W is delivered from the outer circumferential chuck 30 to the center chuck 20A, and the substrate W is held only by the center chuck 20A. At this time, the grippers 32 are not in contact with either the side surface or the lower surface of an outer circumferential portion (a bevel) of the substrate W, and the substrate W is held by the center chuck 20A in a bevel-free state. As necessary, the grippers 32 may be slightly lowered in order to secure an interval between the outer circumferential portion lower surface of the substrate W and the lower surface supporting portions 34 thereof.

In this manner, the liquid process to supply the processing liquid to the surface of the substrate W is performed while rotating the substrate W in a state where the substrate W is held only by the center chuck 20A (step S5; a liquid process; see FIG. 8C). That is, the substrate rotating mechanism 11 is controlled to cause the hybrid chuck 10 to rotate so that the substrate W is rotated around the rotation axis A at a predetermined liquid processing rotation speed (for example, 800 rpm). Also, when the processing liquid valve 17 is opened, the processing liquid is discharged from the processing liquid nozzle 15 toward the surface (here, the upper surface) of the substrate W. After the liquid process is performed for a predetermined liquid process time, the discharge of the processing liquid from the processing liquid nozzle 15 is stopped.

Next, at the start of a drying process of rotating the substrate W around the rotation axis A at a predetermined drying rotation speed (for example, 2500 rpm) to spin off the liquid, the controller 8 controls the cam driving mechanism 51 to control the grippers 32 to the closed state (holding state). That is, the side surface contact portions 33 of the grippers 32 come into contact with the outer circumferential portion side surface of the substrate W, and holding of the substrate by the outer circumferential chuck 30 is started. That is, the substrate W is held at the lower surface center portion by the center chuck 20A and is held at the outer circumferential portion by the outer circumferential chuck 30 (step S6; see FIG. 8D).

The controller 8 executes pressing force control to adjust the pressing force under the control of the cam driving mechanism 51 (step S8). More specifically, the pressing force is controlled by controlling the torque generated by the electric motor 53. The pressing force is controlled to a value smaller than an assumed pressing force required when the substrate W is not held by the center chuck 20A but the substrate W is held only by the outer circumferential chuck 30, and the substrate W is rotated at the drying rotation speed. That is, the torque generated by the electric motor 53 is controlled such that such a pressing force is achieved.

The drying process is performed while performing such pressing force control (step S8). That is, the controller 8 accelerates the rotation speed of the substrate W to the drying rotation speed by controlling the substrate rotating mechanism 11, and maintains the drying rotation speed over a predetermined drying time. Thereafter, the rotation of the substrate W is stopped, and the drying process is terminated.

Next, the controller 8 releases the suctioning holding by the center chuck 20A (vacuum chuck) by closing the suction valve 65 and stopping the suction by the suction head 60 (step S9). As a result, the substrate W is brought into a state where being held only by the outer circumferential chuck 30, and the substrate W is transferred from the center chuck 20A to the outer circumferential chuck 30.

Thereafter, the controller 8 controls the cam driving mechanism 51, thereby brings the grippers 32 into the open state to separate the side surface contact portions 33 from the outer circumferential portion side surface of the substrate W, and further, elevates the grippers 32 to the elevated position in a state where the lower surface supporting portions 34 supports the outer circumferential portion lower surface of the substrate W (step S10; see FIG. 8A). Thereafter, the center robot 6 picks up the processed substrate W from the grippers 32 in the open state and carries out the substrate W (step S11). In this way, the processing on one substrate W is ended.

Since the substrate W can be held in a state where the outer circumferential portion side surface of the substrate W is released by using the center chuck 20A composed of a vacuum chuck, the outer circumferential portion side surface of the substrate can be thoroughly processed in the liquid process. On the other hand, in the drying process, since the substrate W is held also by the outer circumferential chuck 30, it is not necessary to strongly suction the lower surface center portion of the substrate W by the center chuck 20A (vacuum chuck), and thus, it is possible to shorten the drying process time by rotating the substrate W at a high speed while preventing generation of a suction mark. In addition, due to the contribution of the center chuck 20A (the vacuum chuck) to the holding of the substrate W, the pressing force of the grippers 32 of the outer circumferential chuck 30 against the outer circumferential portion side surface of the substrate can be reduced, and it is thereby made possible to prevent a defect or the like in the outer circumferential portion of the substrate W.

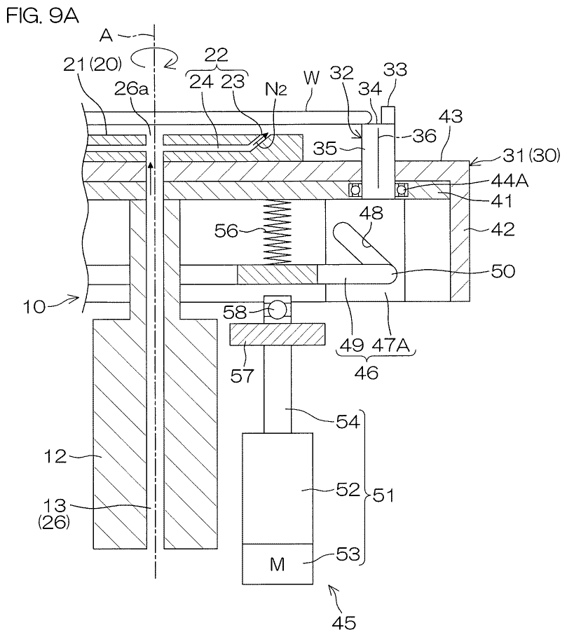

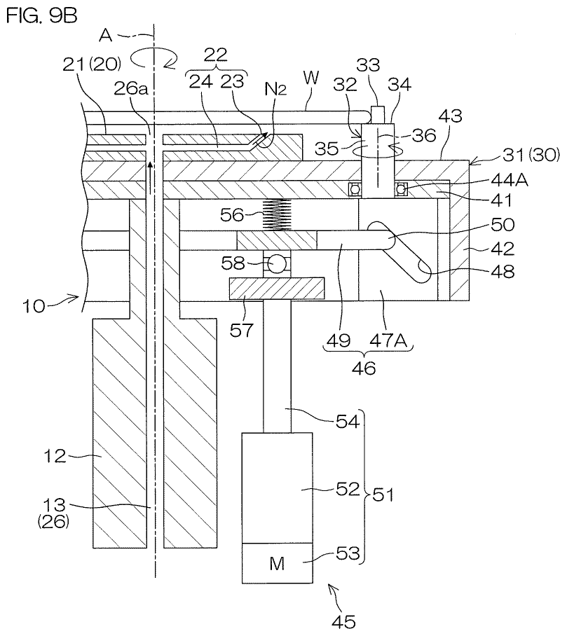

FIGS. 9A and 9B are diagrams for explaining still another preferred embodiment of the present invention, and show another configuration example of the outer circumferential chuck 30. In FIGS. 9A and 9B, the corresponding portions of the parts illustrated in FIGS. 5A, 5B, and 5C are indicated with the same reference signs as in FIGS. 5A, 5B, and 5C. It is noted that, a case where the center chuck 20 is a Bernoulli chuck is exemplified here, but the center chuck may be a vacuum chuck (see FIGS. 8A to 8D).

The outer circumferential base 31 includes a base plate 41 fixed to the shaft 12 and a base cover 42. The base plate 41 is accommodated in the base cover 42. Each of the grippers 32 is coupled to the base plate 41 via a bearing 44A. The gripper 32 includes a shaft portion 35 that passes through the base plate 41 in the up/down direction, further passes through a top surface portion 43 of the base cover 42 and protrudes upward, and the lower surface supporting portion 34 and the side surface contact portion 33 are provided at an upper end portion of the shaft portion 35. The bearing 44 couples the shaft portion 35 of the gripper 32 to the base plate 41 such as to be circumrotatable about the circumrotation axis 36. In this preferred embodiment, the up/down movement of the gripper 32 with respect to the base plate 41 is restricted, and thus the gripper 32 does not have a function as a lift pin. The side surface contact portion 33 is erected at a position eccentric from the circumrotation axis 36. Therefore, the distance between the side surface contact portion 33 and the outer circumferential portion side surface of the substrate W changes by the circumrotation of the gripper 32 about the circumrotation axis 36.

A gripper driving mechanism 45 to turn the gripper 32 around the circumrotation axis 36 is provided. The gripper driving mechanism 45 includes a cam mechanism 46 and a cam driving mechanism 51 that applies a driving force to the cam mechanism 46.

The cam mechanism 46 includes a cam follower 47A fixed to a lower end of the shaft portion 35 of the gripper 32 and the cam lever 49 coupled to the cam follower 47A. The cam lever 49 is accommodated in the base cover 42 and is movable up and down below the base plate 41. The cam follower 47A has the cam groove 48 inclined with respect to the up/down direction, and a drive end 50 of the cam lever 49 is coupled to the cam groove 48. A compression coil spring 56 that pushes down the cam lever 49 is disposed between the cam lever 49 and the lower surface of the base plate 41.

The cam driving mechanism 51 is disposed in a non-rotating system outside the base cover 42. The cam driving mechanism 51 includes the ball-screw mechanism 52, the electric motor 53 that applies a driving force to the ball-screw mechanism 52, and the driving rod 54 that is moved up and down by the ball-screw mechanism 52. A ring-shaped elevating/lowering plate 57 surrounding the rotation axis A is coupled to an upper end of the driving rod 54. A ring-shaped ball bearing 58 surrounding the rotation axis A is disposed between the elevating/lowering plate 57 and the cam lever 49. One bearing ring of the ball bearing 58 is coupled to the elevating/lowering plate 57, and the other bearing ring of the ball bearing 58 faces the cam lever 49 such as to be able to come into contact therewith.

When the elevating/lowering plate 57 is elevated by driving the cam driving mechanism 51, the ball bearing 58 is elevated and comes into contact with the cam lever 49. When the elevating/lowering plate 57 is further elevated, as illustrated in FIG. 9B, the driving force is transmitted to the cam lever 49 via the ball bearing 58, and the cam lever 49 can be elevated while the compression coil spring 56 is compressed. Then, the drive end 50 of the cam lever 49 moves in the cam groove 48 of the cam follower 47A to displace the cam follower 47A radially outward. As a result, the gripper 32 circumrotates around the circumrotation axis 36. As a result, the distance between the side surface contact portion 33 and the rotation axis A is shortened, and the side surface contact portion 33 approaches the outer circumferential portion side surface of the substrate W. As a result, the side surface contact portion 33 can be brought into contact with the outer circumferential portion side surface of the substrate W, and the side surface contact portion 33 can be pressed against the outer circumferential portion side surface of the substrate W. That is, the gripper 32 can be brought into a closed state. The pressing force of the side surface contact portion 33 against the outer circumferential portion side surface of the substrate W is continuously variable by changing the driving force applied from the cam driving mechanism 51 including the ball-screw mechanism 52.

On the other hand, when the elevating/lowering plate 57 is lowered by the cam driving mechanism 51, the compression coil spring 56 pushes down the cam lever 49. As a result, the drive end 50 of the cam lever 49 moves downward in the cam groove 48 to displace the cam follower 47A radially inward. As a result, as illustrated in FIG. 9A, the side surface contact portion 33 is displaced in a direction away from the rotation axis A, and is separated from the outer circumferential portion side surface of the substrate W. As a result, the gripper 32 can be brought into an open state.

The position of the substrate W when the gripper 32 supports the substrate W by the lower surface supporting portion 34 is a transfer position at which the substrate W is transferred between the hand 6a of the center robot 6 (the substrate transfer robot) and the hybrid chuck 10 (more specifically, the outer circumferential chuck 30). This position is also a position where the substrate W can be held by the center chuck 20. Therefore, as illustrated in FIG. 9A, the substrate W can be held by the lower surface center portion of the substrate W by the center chuck 20, and the substrate W can be held by the outer circumferential portion of the substrate W by the outer circumferential chuck 30.

Although preferred embodiments of the present invention have been described above, the present invention can be implemented in yet other preferred embodiments.

For example, in the above-described preferred embodiments, each of the grippers 32 includes the side surface contact portion 33 and the lower surface supporting portion 34, but the lower surface supporting portion may be formed of a member or members other than the gripper 32.

Also, in the above-described preferred embodiments, an example has been described in which the cam driving mechanism 51 has a configuration in which the pressing force of the grippers 32 against the outer circumferential side surface of the substrate is continuously variable, but the pressing force may be variable stepwise. In this case, a drive source of the cam driving mechanism 51 may be an air cylinder. Also, the pressing force is not necessarily variable, and the pressing force of the grippers 32 in the closed state may be designed to be smaller than an assumed pressing force required when the substrate W is held only by the outer circumferential chuck 30 and the substrate W is rotated at a drying rotation speed.

While preferred embodiments of the present invention have been described in detail above, these are merely specific examples used to clarify the technical content of the present invention, and the present invention should not be interpreted as being limited to these specific examples, and the scope of the present invention shall be limited only by the appended claims.

What is claimed is:

1. A substrate processing method comprising:
a liquid process to supply a processing liquid to a surface of a substrate while holding the substrate in a horizontal state by a center chuck that holds the substrate in a lower surface center portion of the substrate; and
a drying process to spin off the liquid on the surface of the substrate by rotating the substrate around a rotation axis along an up/down direction while holding the substrate in a horizontal state by the center chuck and gripping the substrate at an outer circumferential portion of the substrate by an outer circumferential chuck including a plurality of grippers each having a side surface contact portion that comes into contact with an outer circumferential portion side surface of the substrate.

2. The substrate processing method according to claim 1, wherein the side surface contact portion of each of the plurality of grippers is retreated from the outer circumferential portion side surface of the substrate in the liquid process, and is brought into contact with the outer circumferential portion side surface of the substrate in the drying process.

3. The substrate processing method according to claim 1, further comprising a centering process to center the substrate by bringing the side surface contact portion of each of the plurality of grippers into contact with the outer circumferential portion side surface of the substrate, wherein
after the centering process, the liquid process is performed by retreating the side surface contact portion of each of the plurality of grippers from the outer circumferential portion of the substrate and bringing the side surface contact portion of each of the plurality of grippers into a non-contact state of not being in contact with the substrate.

4. The substrate processing method according to claim 1, wherein, in the drying process, the substrate is rotated around the rotation axis at a predetermined drying rotation speed, and the side surface contact portion of each of the plurality of grippers is pressed against the outer circumferential portion side surface of the substrate with a pressing force smaller than an assumed pressing force required when the substrate is rotated at the drying rotation speed while being held by the outer circumferential chuck without being held by the center chuck.

5. The substrate processing method according to claim 1, further comprising an elevating/lowering process to move the lower surface supporting portion up and down relative to the center chuck in a state where the substrate is supported from below by the lower surface supporting portion in contact with an outer circumferential portion lower surface of the substrate.

6. The substrate processing method according to claim 5, wherein each of the plurality of grippers includes the lower surface supporting portion.

7. The substrate processing method according to claim 1, wherein the center chuck includes a Bernoulli chuck.

8. The substrate processing method according to claim 1, wherein the center chuck includes a vacuum chuck.

9. A substrate processing apparatus comprising:
a hybrid chuck including a center chuck to hold a substrate at a lower surface center portion of the substrate and an outer circumferential chuck that includes a plurality of grippers that come into contact with an outer circumferential portion side surface of the substrate, the center chuck and the outer circumferential chuck being disposed to share a predetermined rotation axis along a vertical direction;
a lift to move the plurality of grippers up and down relative to the center chuck; and
a gripper actuator to displace the plurality of grippers between a closed state where each of the plurality of grippers is in contact with the outer circumferential portion side surface of the substrate and an open state where each of the plurality of grippers is retreated from the outer circumferential portion side surface of the substrate.

10. The substrate processing apparatus according to claim 9, wherein each of the plurality of grippers includes a side surface contact portion that comes into contact with the outer circumferential portion side surface of the substrate and a lower surface supporting portion that comes into contact with an outer circumferential portion lower surface of the substrate.

11. The substrate processing apparatus according to claim 10, further comprising a controller configured or programmed to control the lift and the gripper actuator, wherein
the controller is configured or programmed
to move the plurality of grippers up and down relative to the center chuck in a state where the substrate is supported from below by the lower surface supporting portion.

12. The substrate processing apparatus according to claim 11, wherein
the controller is configured or programmed to further control the center chuck, and wherein
the controller is configured or programmed to bring the side surface contact portion of each of the plurality of grippers into contact with the outer circumferential portion side surface of the substrate to perform centering of the substrate, then retreat the side surface contact portion from the outer circumferential portion side surface of the substrate, and thereafter causes the center chuck to hold the substrate.

13. The substrate processing apparatus according to claim 9, further comprising:
a processing liquid nozzle to supply a processing liquid to the substrate held by the hybrid chuck; and
a controller configured or programmed to control the center chuck and the outer circumferential chuck, wherein
the controller is configured or programmed
to control the center chuck to be in a holding state in which the center chuck holds the substrate and to control the outer circumferential chuck to be in a non-holding state in which the outer circumferential chuck is not in contact with the substrate in a liquid process in which the processing liquid is supplied from the processing liquid nozzle to the substrate held by the hybrid chuck, and
to control both the center chuck and the outer circumferential chuck to be in a holding state in which both the center chuck and the outer circumferential chuck hold the substrate in a drying process to stop supplying of the processing liquid from the processing liquid nozzle and to dry the substrate by rotating the substrate at a predetermined drying rotation speed around the rotation axis.

14. The substrate processing apparatus according to claim 13, wherein the controller is configured or programmed to rotate the substrate around the rotation axis at the predetermined drying rotation speed, and to control the gripper actuator such that the plurality of grippers are pressed against the outer circumferential portion side surface of the substrate with a pressing force smaller than an assumed pressing force required when the substrate is rotated at the predetermined drying rotation speed while being held by the outer circumferential chuck without being held by the center chuck, in the drying process.

15. The substrate processing apparatus according to claim 14, wherein the gripper actuator is configured to vary the pressing force of the plurality of grippers against the outer circumferential portion side surface of the substrate.

16. The substrate processing apparatus according to claim 9, wherein the center chuck includes a Bernoulli chuck.

17. The substrate processing apparatus according to claim 9, wherein the center chuck includes a vacuum chuck.
